(19) United States
(12) Patent Application Publication
(10) Pub. No.: US 2005/0064111 A1
(43) Pub. Date: Mar. 24, 2005

(54) Method for forming doping superlattices using standing electromagnetic waves

(76) Inventor: Nathan David Hiller, San Diego, CA (US)

Correspondence Address: Nathan David Hiller, 1323 Banyan Drive, Fallbrook, CA, 92028, US

(21) Appl. No.: 10/810,450

(22) Filed: Mar. 26, 2004

Related U.S. Application Data
(63) Continuation-in-part of application No. 10/669,449, filed on Sep. 23, 2003.

(51) Int. Cl. H01L 29/06; H01L 31/0328; H01L 31/0336; H01L 31/072; H01L 31/109; H05B 6/00; C23C 14/28

(52) U.S. Cl. 427/595

(57) ABSTRACT

A method for forming doping superlattices in doped bulk semiconductors using one or more standing electromagnetic waves is disclosed. Using a standing optical beam comprising of optical beats (47) a uniformly doped bulk semiconductor (21) is converted into a doping superlattice comprising of planes (57). Using two and three standing optical beams comprising of optical beats, oriented perpendicular to one another, a doping superlattice comprising of a two dimensional array of wires (108), and a doping superlattice comprising of a three dimensional array of dots (112) can be formed, respectively.

### CROSS-REFERENCE TO RELATED APPLICATIONS

This patent application is a continuation-in-part application of U.S. patent application Ser. No. 10/669,449, filed Sep. 23, 2003.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

This invention relates to methods for forming doping superlattices, specifically to periodic electronic potential structures arising from a periodic variation in the density of impurities or dopants in a bulk semiconductor.

Doping superlattices are periodic electronic potential structures that are composed of a periodic variation in the density of impurities or dopants in a single semiconductor. The unique electrical and optical properties of doping superlattices could lead to variety of novel devices relating to photodetectors, tunable light sources, spatial light modulators, optical amplifiers, optical switches, saturable absorbers, and optical bistability.

The major problems with the methods used to form doping superlattices is that each method uses a layer-by-layer approach, which by its nature is a slow process, requires expensive equipment, and is limited to doping superlattices comprising of layers only. Additionally, large scale devices and components have not been developed because current fabrication processes cannot produce large volumes, cubes, or blocks of doping superlattices.

Doping superlattices in semiconductors was first proposed by Esaki and Tsu in the IBM Journal of Research and Development, volume 14, page 61, 1970.

The first doping superlattice comprising of a p-n-p-n layered structure was fabricated by Ovsyannikov et al, and disclosed in Soviet Physics—Semiconductors, volume 4, no. 12, page 1919, 1970. The doping superlattice fabricated by Ovsyannikov et al, consisted of silicon. The n and p layer thicknesses ranged from 200 nm to 1,000 nm and 30 periods were formed.

The first doping superlattice comprising of a n-i-p-i layered structure was fabricated using molecular beam epitaxy by Ploog et al, and disclosed in the Journal of the Electrochemical Society, volume 128, page 400, 1981. The doping superlattice fabricated by Ploog et al, consisted of GaAs where Be dopant was used as the acceptor to form the p-layers and Si dopant was used as the donor to form the n-layers. Each n and p layer was as thick as 100 nm and 10 periods were formed.

A doping superlattice comprising of a n-i-p-i layered structure was fabricated using hydride vapor phase epitaxy by Yamauchi et al, and disclosed in the Japanese Journal of Applied Physics, volume 23, number 10, page L785, 1984. The doping superlattice fabricated by Yamauchi et al, consisted of InP where Zn dopant was used as the acceptor to form the p-layers and S dopant was used as the donor to form the n-layers. The thickness of the n and p layers ranged from 15 nm to 200 nm.

A doping superlattice comprising of a n-i-p-i layered structure was fabricated using a modified hot-wall technique by Jantsch et al, and disclosed in the Applied Physics Letters, volume 47, number 7, page 738, 1985. The doping superlattice fabricated by Jantsch et al, consisted of PbTe where the n layers were 93 nm thick and the p layers were 135 nm thick.

A doping superlattice comprising of a n-i-p-i layered structure was fabricated using organometallic vapor-phase epitaxy by Kitamura et al, and disclosed in the Journal of Applied Physics, volume 61, number 4, page 1533, 1987. The doping superlattice fabricated by Kitamura et al, consisted of GaP where Te dopant and Zn dopant were used to form the n and p layers. Each n and p layer was 20 nm thick and 40 periods were formed.

The main problem with each of the methods used to fabricate doping superlattices as described thus far is that the doping superlattice layers cannot be formed simultaneously because each layer provides the structural support for the next layer. Thus, only one layer can be formed at a time, which by nature is slow. To produce large volumes, cubes or blocks of doping superlattice using these fabrication techniques requires long fabrication times and expensive equipment. Furthermore, these fabrication techniques cannot form pure two and three-dimensional structured doping superlattices such as two dimensional arrays of wires and three dimensional arrays of dots.

### BRIEF SUMMARY OF THE INVENTION

In accordance with the present invention a method for forming doping superlattices using standing electromagnetic waves. The doping superlattices formed are a result of a periodic variation in the density of impurities or dopants in a bulk semiconductor. This periodically graded dopant or impurity density is formed from a uniform dopant density using a standing electromagnetic wave. The type of standing electromagnetic wave used is a standing optical beam comprising of optical beats.

Accordingly, several objects and advantages of my invention are:

a) to provide a method for forming a doping superlattice in the form of layers in a bulk semiconductor where each layer is formed simultaneously;
b) to provide a method for forming a doping superlattice in the form of a two dimensional array of wires in a bulk semiconductor where each wire is formed simultaneously;
c) to provide a method for forming a doping superlattice in the form of a three dimensional array of dots in a bulk semiconductor where each dot is formed simultaneously;
d) to provide a method for forming a doping superlattice in a bulk semiconductor where the doping lattice structure has a consistent spacing or period.

Another object and advantage is to provide a method for forming doping superlattices, which can later be altered and/or easily recycled. Still further objects and advantages of my invention will become apparent from a consideration of the ensuing description and drawings.

### BRIEF DESCRIPTION OF THE SEVERAL VIEWS OF THE DRAWING

In the drawings, closely related figures and parts have the same number but different alphabetical suffixes.

FIGS. 1A to 1B show a uniformly doped bulk semiconductor and a associated energy band diagram.

FIGS. 2A to 2C show the process of converting the uniformly doped bulk semiconductor to a doping superlattice comprising of planes using a standing optical beam comprising of optical beats.

FIG. 3 shows a periodic well-shaped energy band diagram associated with the doping superlattice comprising of planes as shown in FIG. 2C.

FIG. 4 shows the uniformly doped bulk semiconductor in the path of the standing optical beam comprising of optical beats, which is created by splitting and overlapping of two optical beams, and then overlapping them in opposite directions inside a vacuum chamber.

FIG. 5A to 5C show the process of converting the uniformly doped bulk semiconductor to a doping superlattice comprising of a two dimensional array of wires, and a doping superlattice comprising of a three dimensional array of dots, using more than one standing optical beam comprising of optical beats.

### REFERENCE NUMERALS IN DRAWINGS

20 bulk semiconductor
21 uniformly doped bulk semiconductor
22 dopant A
24 conduction energy band edge
26 fermi energy level
29 valence energy band edge
32 energy band diagram
35 periodic well-shaped energy band diagram
43 arrow
44a optical beam A comprising of optical beats
44b optical beam B comprising of optical beats
44c optical beam C comprising of optical beats
44d optical beam D comprising of optical beats
45 thickness of bulk semiconductor
47 standing optical beam comprising of optical beats
48 plane of electric field nodes
50 plane of electric field anti-nodes
52 points of peak electric field intensity
54 points of minimum electric field intensity
56 distance between two neighboring planes comprising of a high density of dopant A
57 doping superlattice comprising of planes
59 plane comprising of a high density of dopant A
60 plane comprising of a low density of dopant A
61 well-shaped region containing a high density of conduction electrons
63 well-shaped region containing a high density of valence holes
74a optical beam A
74b optical beam B
76a laser A
76b laser B
80a optical isolator A
80b optical isolator B
86 beam splitter
88a reflector A
88b reflector B
92 electric heater fixture
96 vacuum chamber
98 vacuum pump
100 plane of electric field nodes
102 standing optical beam comprising of optical beats
104 region comprising of a low density of dopant A
106 wire comprising of a high density of dopant A
108 doping superlattice comprising of a two dimensional array of wires
110 dot comprising of a high density of dopant A
112 doping superlattice comprising of a three dimensional array of dots

### DETAILED DESCRIPTION OF THE INVENTION

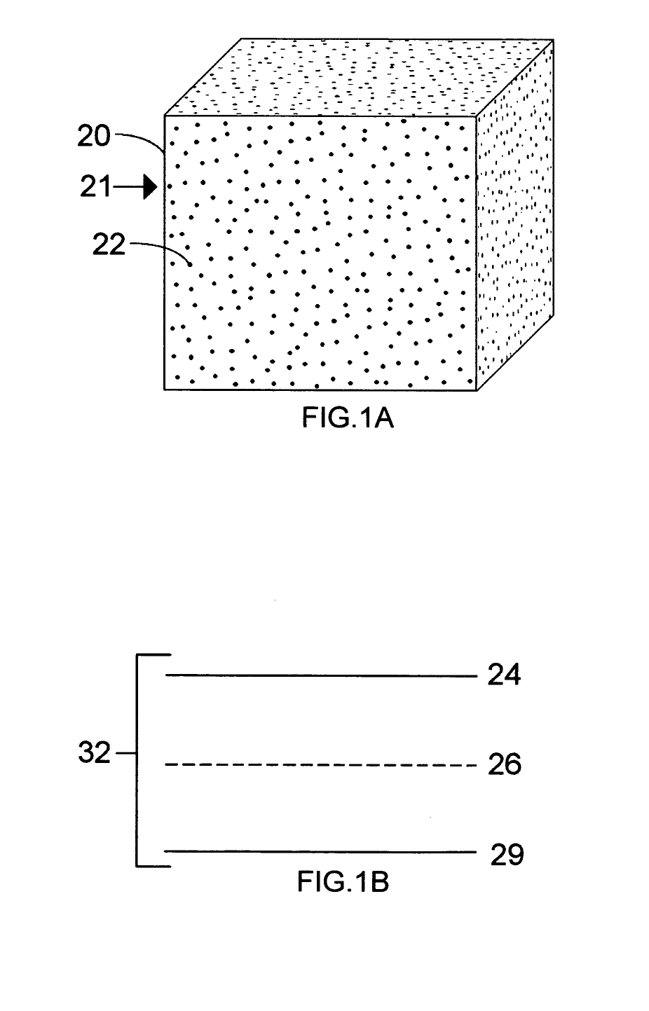

FIGS. 1A to 1B show a uniformly doped bulk semiconductor 21, and the associated energy band diagram 32. In FIG. 1A a dopant A 22 is uniformly distributed throughout a bulk semiconductor 20. Not shown in FIG. 1A is a second dopant B which is also uniformly distributed throughout the bulk semiconductor 20. In the bulk semiconductor 20 dopant B has a low thermal diffusion coefficient relative to the thermal diffusion coefficient of dopant A 22. Dopant A 22 and dopant B have opposite charge states in the bulk semiconductor 20 such that if dopant A 22 is a donor then dopant B is an acceptor. Alternatively, if dopant A 22 is an acceptor then dopant B is a donor. The density of dopant A 22 is equal to the density of dopant B in the bulk semiconductor 20, thus the uniformly doped bulk semiconductor 21 is compensated to a neutral state.

FIG. 1B shows a energy band diagram 32 for the uniformly doped bulk semiconductor 21, which consists of a conduction energy band edge 24, a fermi energy level 26, and a valence energy band edge 29, listed in the order of decreasing energy. The energy band diagram 32 in FIG. 1B is a constant or flat electronic potential structure for the uniformly doped bulk semiconductor 21.

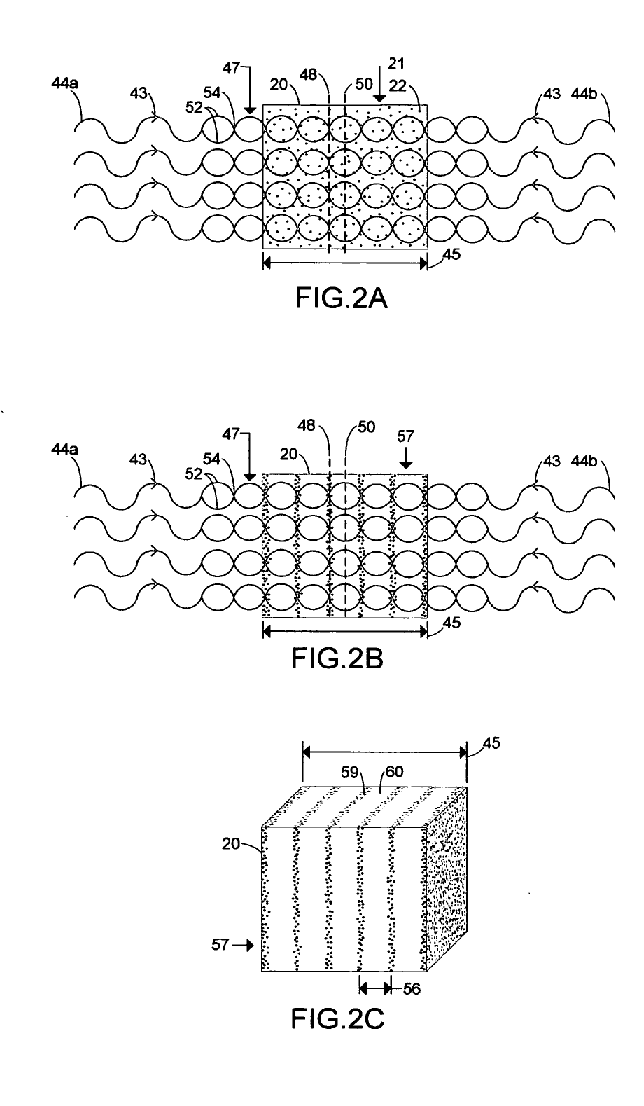

FIGS. 2A to 2C show the process of converting the uniformly doped bulk semiconductor 21 to a doping superlattice comprising of planes 57 using a standing optical beam comprising of optical beats 47. In FIGS. 2A and 2B the standing optical beam comprising of optical beats 47 is established inside the uniformly doped bulk semiconductor 21 by overlapping a optical beam A comprising of optical beats 44a and a optical beam B comprising of optical beats 44b, which are propagating parallel to one another in opposite directions inside the uniformly doped bulk semiconductor 21. An arrow 43 indicates the direction in which each optical beam is propagating. The optical beams comprising of optical beats propagate in a straight line but are shown as a wavy or rippled line to illustrate their wave nature. The standing optical beam comprising of optical beats 47 has time varying points of a peak electric field intensity 52 which are defined as anti-nodes and time varying points of a minimum electric field intensity 54 which are defined here as nodes. The points of a peak electric field intensity 52 lie in a plane of electric field anti-nodes 50 and the points of a minimum electric field intensity 54 lie in a plane of electric field nodes 48. Due to the non-zero absorption coefficient for the optical beams, each optical beam intensity is reduced after propagating a thickness of the bulk semiconductor 45. This reduction in the optical beams intensity results in a decrease in the quality of the standing optical beam comprising of optical beats 47 with increasing distance from the center of the bulk semiconductor 20.

In FIGS. 2A and 2B both optical beams are coherent and have the same linear polarization orientation. The surfaces in which the optical beams enter and exit the uniformly doped bulk semiconductor 21 are flat and parallel to one another. The standing optical beam comprising of optical beats 47 is concentric or centered to the uniformly doped bulk semiconductor 21.

The process of converting the uniformly doped bulk semiconductor 21 to the doping superlattice comprising of planes 57 using the standing optical beam comprising of optical beats 47, as illustrated in FIGS. 2A to 2C, can be explained by the position dependent diffusion enhancement of the dopant A 22. The photons in the optical beams have an energy near the bulk semiconductor 20 band gap energy. As the optical beams pass through the uniformly doped bulk semiconductor 21, a small fraction of these photons are absorbed by valence electrons in the valence band resulting in the creation of hole-electron pairs in the uniformly doped bulk semiconductor 21. The dopant A 22 and the dopant B tend to serve as recombination centers so a fraction of the excited electrons and holes recombine at the dopant A 22 and the dopant B sites. The energy released during the electron-hole recombination sometimes takes the form of one or more phonons. This phonon emission results in a “thermal spike” at the dopant A 22 sites and the dopant B sites. The “thermal spike” is a temporary increase in the dopant A 22 temperature and the dopant B temperature and results in an order of magnitude increase in the dopant A 22 thermal diffusion rate and the dopant B thermal diffusion rate in the bulk semiconductor 20. This phenomenon is called “Recombination Enhanced Diffusion” and is described by Kimerling in the IEEE Transactions on Nuclear Science, volume NS-23, number 6, page 1497, December 1976. However, as previously stated dopant B has a low thermal diffusion coefficient relative to the thermal diffusion coefficient of dopant A 22, thus the enhanced thermal diffusion rate of dopant A 22 is orders of magnitude greater than the enhanced diffusion rate of dopant B. In other words, the activation energy of dopant B is much greater than the activation energy of dopant A 22, thus the dopant B will be considered to have a fixed distribution within the uniformly doped bulk semiconductor 22 in spite of it's enhanced diffusion. The thermal diffusion rate and enhanced diffusion rate of dopant B will be considered to be zero from this point forward, thus only the thermal diffusion of dopant A 22 will be considered.

Dopant A 22 has the highest probability of serving as a recombination center in or near the plane of electric field anti-nodes 50 because the highest density of electron-hole pairs are created and exist in the plane of electric field anti-nodes 50. Dopant A 22 has the lowest probability of serving as a recombination center in or near the plane of electric field nodes 48 because the lowest density of electron-hole pairs are created and exist in the plane of electric field nodes 48. The electrons and holes tend to diffuse away from the location in which they were created, however this diffusion distance is relatively small because the diffusion length of the electrons and holes are much less than the distance between a given plane of electric field anti-nodes 50 and a neighboring plane of electric field nodes 48. The periodic anisotropic or spatially dependent diffusion rates of the dopant A 22 within the bulk semiconductor 20 results in a periodic spatial distribution of dopant A 22 within the bulk semiconductor 20 over time.

After applying the standing optical beam comprising of optical beats 47 to the uniformly doped bulk semiconductor 21 for some period of time, the density of dopant A 22 in the plane of electric field nodes 48 increases significantly above the density of dopant A 22 in the original uniformly doped bulk semiconductor 21. The density of dopant A 22 in the plane of electric field anti-nodes 50 decreases significantly below the density of dopant A 22 in the original uniformly doped bulk semiconductor 21. As a result, a plane comprising of a high density of dopant A 59 and a plane comprising of a low density of dopant A 60 is formed simultaneously in an alternating fashion and parallel to one another within the bulk semiconductor 20 as shown in FIG. 2C. A plane comprising of a high density of dopant A 59 and a plane comprising of a low density of dopant A 60 is formed simultaneously in an alternating fashion and parallel to one another within the bulk semiconductor 20 as shown in FIG. 2C. The term high density in this case is defined as greater than the density of dopant A 22 in the original uniformly doped bulk semiconductor 21. The term low density in this case is defined as less than the density of dopant A 22 in the original uniformly doped bulk semiconductor 21. For λ_{A}≠λ_{B} a distance between two neighboring planes comprising of a high density of dopant A 56 is λ_{A}λ_{B}/(n_{A}λ_{B}−n_{B}λ_{A}) where λ_{A} is the wavelength of optical beam A 74a in a vacuum, λ_{B} is the wavelength of optical beam B 74b in a vacuum, n_{A} is the index of refraction for optical beam A 74a in the bulk semiconductor 20, and n_{B} is the index of refraction for optical beam B 74b in the bulk semiconductor 20. If λ_{A}=λ_{B} then the distance between two neighboring planes comprising of a high density of dopant A 56 is λ_{A}/(2n_{A}). If laser A 76A is on and laser B 76B is off then the distance between two neighboring planes comprising of a high density of dopant A 56 is λ_{A}/(2n_{A}). The boundary between a given plane comprising of a high density of dopant A 59 and a neighboring plane comprising of a low density of dopant A 60 is graded in dopant A 22 density rather than discontinuous in a step like fashion. The final doping superlattice comprising of planes 57 is shown in FIG. 2C.

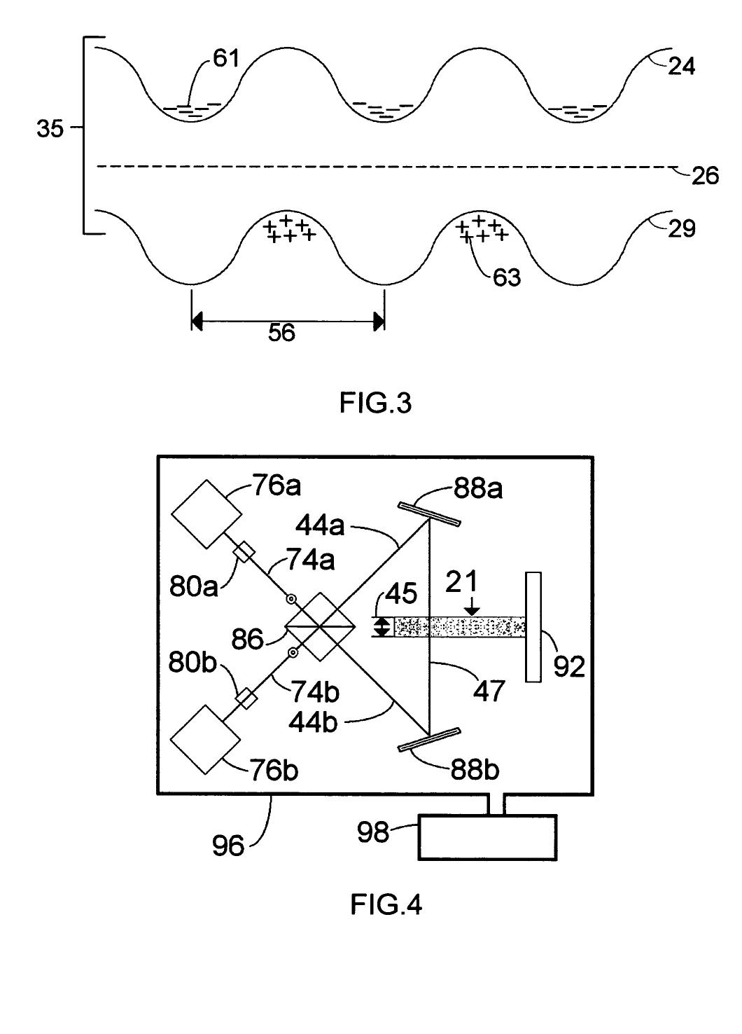

FIG. 3 shows a periodic well-shaped energy band diagram 35 associated with the doping superlattice comprising of planes 57 shown in FIG. 2C in the case that dopant A 22 is a electron donor and dopant B is a electron acceptor. A well-shaped region containing a high density of conduction electrons 61 exists slightly above the conduction energy band edge 24. A well-shaped region containing a high density of valence holes 63 exists slightly below the valence energy band edge 29.

In FIG. 3 the well-shaped regions containing a high density of conduction electrons 61 exists because the planes comprising of a high density of dopant A 59 are of a higher density than the density of dopant B in this region. In other words, the bulk semiconductor 20 is compensated such that it is n-type in this region. For each plane comprising of a high density of dopant A 59 in the bulk semiconductor 20 shown in FIG. 2C, there exists a corresponding well-shaped region containing a high density of conduction electrons 61 in the energy band diagram shown in FIG. 3.

In FIG. 3 the well-shaped regions containing a high density of valence holes 63 exist because the planes comprising of a low density of dopant A 60 are of a lower density than the density of dopant B in this region. In other words, the bulk semiconductor 20 is compensated such that it is p-type in this region. For each plane comprising of a low density of dopant A 60 in the bulk semiconductor 20 shown in FIG. 2C, there exists a corresponding well-shaped region containing a high density of valence holes 63 in the energy band diagram shown in FIG. 3.

In FIG. 3 the distance between two neighboring well-shaped regions containing a high density of conduction electrons is equal to the distance between two neighboring planes comprising of a high density of dopant A 56. The periodic well-shaped energy band diagram 35 in FIG. 3 is a periodic electronic potential structure.

FIG. 4 shows the equipment used to create the standing optical beam comprising of optical beats 47 shown in FIGS. 2A and 2B. The uniformly doped bulk semiconductor 21, the optical beam A comprising of optical beats 44a, and the optical beam B comprising of optical beats 44b of FIG. 2A are shown inside a vacuum chamber 96 in FIG. 4. FIG. 4 shows the uniformly doped bulk semiconductor 21 in the path of the standing optical beam comprising of optical beats 47, which is created by splitting and overlapping of a two optical beams, and then overlapping them in opposite directions inside a vacuum chamber.

Inside the vacuum chamber 96 a laser A 76a and a laser B 76b create a optical beam A 74a and a optical beam B 74b, respectively. Both laser A 76a and a laser B 76b provide constant wave power output. Optical beam A 74a and optical beam B 74b have slightly different wavelengths and they propagate through a optical isolator A 80a and optical isolator B 80b, respectively. After passing through the optical isolators, optical beam A 74a and optical beam B 74b have the same linear polarization orientation and they intersect perpendicular to one another at the center of a beam splitter 86. The beam splitter 86 is a non-polarizing beam splitter cube, which acts as a 50% partially silvered mirror for both optical beams. After passing through the beam splitter 86, half of optical beam A 74a overlaps half of optical beam B 74b, which as a sum results in optical beam A comprising of optical beats 44a. Likewise, half of optical beam B 74b overlaps half of optical beam A 74a, which as a sum results the optical beam B comprising of optical beats 44b. After optical beam A comprising of optical beats 44a and optical beam B comprising of optical beats 44b reflect from a reflector A 88a and reflector B 88b, respectively, they propagate in opposite directions and parallel to one another and they overlap each other which as a sum result in the standing optical beam comprising of optical beats 47. The standing optical beam comprising of optical beats 47 propagates through and exists within a portion of the uniformly doped bulk semiconductor 21.

An electric heater in fixture 92 maintains the uniformly doped bulk semiconductor 21 at a predetermined temperature while the standing optical beam comprising of optical beats 47 forms the planes comprising of a high density of dopant A 59 and planes comprising of a low density of dopant A 60 inside of the bulk semiconductor 20 as illustrated in FIGS. 2A and 2B. To pump down and maintain a vacuum in the vacuum chamber 96 a vacuum pump 98 connected to the vacuum chamber is operated as needed. Vacuum is defined here as a gas pressure of less than or equal to 1 millitorr. The vacuum minimizes convection gas currents that may disrupt the standing optical beam comprising of optical beats 47 and protects the surface of the bulk semiconductor 20 from oxidizing.

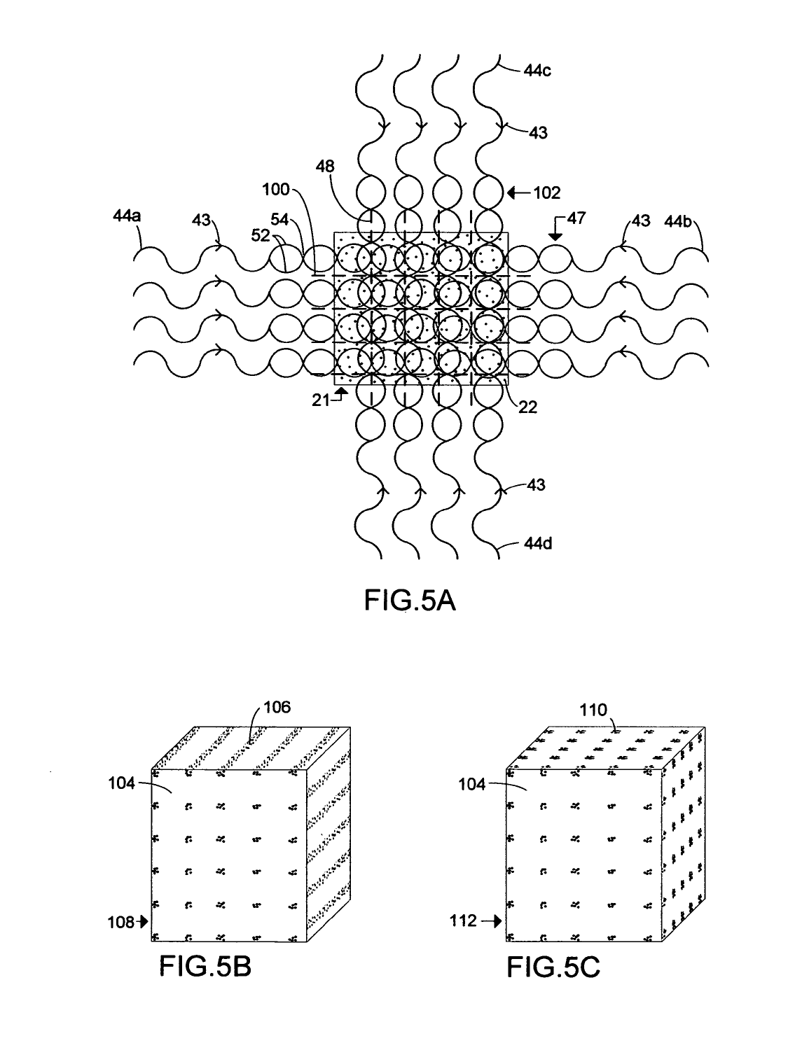

FIG. 5A shows the process of converting the uniformly doped bulk semiconductor 21 to a doping superlattice comprising of a two dimensional array of wires 108 using the standing optical beam comprising of optical beats 47 and a standing optical beam comprising of optical beats 102. In FIG. 5A the standing optical beam comprising of optical beats 47 is established inside the uniformly doped bulk semiconductor 21 by the overlapping of the optical beam A comprising of optical beats 44a and the optical beam B comprising of optical beats 44b, which are propagating parallel to one another in opposite directions. The second standing optical beam comprising of optical beats 102 is established inside the uniformly doped bulk semiconductor 21 by the overlapping of a optical beam C comprising of optical beats 44c and a optical beam D comprising of optical beats 44d, which are propagating parallel to one another in opposite directions. The arrow 43 indicates the direction in which each optical beam is propagating. The standing optical beam comprising of optical beats 47 is perpendicular to the standing optical beam comprising of optical beats 102. The planes of electric field nodes 48 are caused by the standing optical beam comprising of optical beats 47. A plane of electric field nodes 100 is caused by the standing optical beam comprising of optical beats 102. The optical beams propagate in a straight line but are shown as a wavy or rippled lines to illustrate their wave nature. In FIG. 5A the surfaces in which the optical beams enter and exit the uniformly doped bulk semiconductor 21 are flat. Each standing optical beam is concentric or centered to the uniformly doped bulk semiconductor 21.

The process of converting the uniformly doped bulk semiconductor 21 to a doping superlattice comprising of a two dimensional array of wires 108 using the standing optical beams comprising of optical beats 47 and 102, as illustrated in FIG. 5A, can be explained by the position dependence of the diffusion enhancement of the dopant A 21 as previously described for the doping superlattice comprising of planes 57 in FIGS. 2A and 2B. However, due to the fact that two standing optical beams comprising of optical beats exist in FIG. 5A, it is the intersections of the planes of electric field nodes 48 and 100 that have minimum electric field intensities. These intersections form lines in FIG. 5A, not planes, as is the case in FIGS. 2A and 2B. As a result, the dopant A 22 has the lowest probability of serving as a recombination center in or near the intersections of the planes of electric field nodes 48 and 100 because the lowest density of electron-hole pairs are created and exist in these intersections of the planes of electric field nodes 48 and 100. The periodic anisotropic or spatially dependent diffusion rates of the dopant A 22 within the bulk semiconductor 20 results in a periodic spatial distribution of the dopant A 22 within the bulk semiconductor 20 over time.

After applying the two the standing optical beams comprising of optical beats 47 and 102 to the uniformly doped bulk semiconductor 21 for some period of time, the density of the dopant A 22 in the intersections previously described, will have increased above the density of dopant B in the same intersection regions of the bulk semiconductor 20. As a result, a wire comprising of a high density of dopant A 106 or N-type wire and a region comprising of a low density of dopant A 104 or p-type region forms simultaneously in an array-like pattern as shown in FIG. 5B. The term high density in this case is defined as greater than the density of dopant A 22 in the original uniformly doped bulk semiconductor 21. The term low density in this case is defined as less than the density of dopant A 22 in the original uniformly doped bulk semiconductor 21. The boundary between a wire comprising of a high density of dopant A 106 and its neighboring region comprising of a low density of dopant A 104 is graded in dopant A 22 density rather than discontinuous in a step like fashion. The final doping superlattice comprising of a two dimensional array of wires 108 is shown in FIG. 5B. In this case it was assumed that dopant A 22 is an electron donor and the dopant B is an electron acceptor.

If a third standing optical beam comprising of optical beats, oriented perpendicular to the other two standing optical beams comprising of optical beats 47 and 102, is applied to the uniformly doped bulk semiconductor 21 in FIG. 5A, then the intersections of all three of the planes of electric field nodes have the minimum electric field intensities. After applying the three standing optical beams comprising of optical beats to the uniformly doped bulk semiconductor 21 for some period of time, the density of dopant A 22 in the intersections previously described, will have increased above the density of dopant B in the same intersecting regions of the bulk semiconductor 21. As a result, a dot comprising of a high density of dopant A 110 or n-type dot is formed in FIG. 5C. The final form of the uniformly doped bulk semiconductor 21 is a doping superlattice comprising of a three dimensional array of dots 112 as shown in FIG. 5C.

Operation

I. Open vacuum chamber 96 and secure uniformly doped bulk semiconductor 21 to the electric heater fixture 92.
II. Provide power to laser A 76a and laser B 76b and fine-tune them to predetermined wavelengths. If one wants to minimize the distance between two neighboring planes comprising of a high density of dopant A 56, only one laser should be turned on or both lasers should be turned on and tuned to the same wavelength.
III. Adjust parts 76a, 76b, 80a, 80b, 86, 88a, 88b, and 92 as needed such that a standing optical beam comprising of optical beats 47 exists within the uniformly doped bulk semiconductor 21 as described in FIGS. 2A and 2B.
IV. Seal vacuum chamber 96 and using vacuum pump 98 pump gas out of vacuum chamber 96 until a vacuum chamber 96 gas pressure of 1 mtorr is obtained. Maintain this pressure using the vacuum pump 98 as needed.
V. Provide electrical power to electric heater fixture 92 such that the uniformly doped bulk semiconductor 21 is maintained at an elevated predetermined temperature.
VI. After some period of time, turn off electric heater fixture 92 and allow the doping superlattice comprising of planes 57 to cool to room temperature.
VII. Simultaneously shut down laser A 76a and laser B 76b.
VIII. Turn off vacuum pump 98 and backfill vacuum chamber 96 with gas such that it's pressure rises to room pressure.
IX. Open vacuum chamber 96, the doping superlattice comprising of planes 57 from the vacuum chamber 96.
X. Maintain the doping superlattice comprising of planes 57 at temperature of choice.

In this invention there are many materials, dopants, and laser sources that can be used as the bulk semiconductor 20, the dopant A 22, dopant B, and the lasers A and B 76a and 76b, respectively. Four examples are as follows.

### EXAMPLE 1

In example 1 the bulk semiconductor 20 is a 1 mm thick silicon wafer, the dopant A 22 is lithium, dopant B is boron, the uniformly doped bulk semiconductor 21 is a 1 mm thick, 6 inch diameter silicon wafer doped with 10¹⁵ lithium atoms per cm³ and 10¹⁵ boron atoms per cm³. Lithium is an electron donor and boron is an electron acceptor. The saw used to cut the silicon wafer from a crystal ingot is a diamond-tipped inner-hole blade saw. The silicon wafer is mechanically lapped and ground on both sides to obtain a flat surface. To give the wafer a mirror like finish it is polished using a slurry of fine SiO₂ particles in basic NaOH solution. Laser A 76a and Laser B 76b are constant wave diode tunable lasers from New Focus, 2584 Junction Ave, San Jose, Calif., 95134. The part number for the diode tunable lasers is TLB-6324. Laser A 76A is tuned to 1.320 μm and laser B 76B is tuned to 1.316 μm. Optical isolator A 80a and optical isolator B 80b use Faraday Rotators with Yttrium Iron Garnet crystals as the Faraday media. The uniformly doped bulk semiconductor's 21 temperature is maintained between 370° C. and 390° C. while it undergoes steps V-VI as described in the operations section of this invention. The time between operations steps V-VI is 72 hours. If laser A 76A and laser B 76B are both on and operating at 25° C. at a power level between 8.0 mW and 8.5 mW during steps V-VI then the distance between two neighboring planes comprising of a high density of dopant A 56 will be between 120 μm and 130 μm. If laser A 76A is on and operating at 25° C. at a power level between 8.0 mW and 8.5 mW while laser B 76B is off and not operating during steps V-VI then the distance between two neighboring planes comprising of a high density of dopant A 56 will be between 183 nm and 193 nm. The gas removed from vacuum chamber 96 in operation step IV is air. The gas used to backfill vacuum chamber 96 in operation step VIII is argon. After completing operation step IX the doping superlattice comprising of planes 57 is maintained at 173° K.

### EXAMPLE 2

In example 2 the bulk semiconductor 20 is a 1 mm thick silicon wafer, the dopant A 22 is lithium, dopant B is boron, the uniformly doped bulk semiconductor 21 is a 1 mm thick, 6 inch diameter silicon wafer doped with 10¹⁵ lithium atoms per cm³ and 10¹⁵ boron atoms per cm³. Lithium is an electron donor and boron is an electron acceptor. The saw used to cut the silicon wafer from a crystal ingot is a diamond-tipped inner-hole blade saw. The silicon wafer is mechanically lapped and ground on both sides to obtain a flat surface. To give the wafer a mirror like finish it is polished using a slurry of fine SiO₂ particles in basic NaOH solution. Laser A 76a and Laser B 76b are constant wave GaInNAs vertical external-cavity surface emitting lasers as described by Hopkins et al, and disclosed in Electronics Letters, volume 40, number 1, page 30, January 2004. Laser A 76A has an output wavelength at 1.320 μm and laser B 76B has an output wavelength at 1.316 μm. Optical isolator A 80a and optical isolator B 80b use Faraday Rotators with Yttrium Iron Garnet crystals as the Faraday media. The uniformly doped bulk semiconductor's 21 temperature is maintained between 370° C. and 390° C. while it undergoes steps V-VI as described in the operations section of this invention. The time between operations steps V-VI is 72 hours. If laser A 76A and laser B 76B are both on and operating at 5° C. at a power level between 600 mW and 590 mW during steps V-VI then the distance between two neighboring planes comprising of a high density of dopant A 56 will be between 120 μm and 130 μm. If laser A 76A is on and operating at 5° C. at a power level between 600 mW and 590 mW while laser B 76B is off and not operating during steps V-VI then the distance between two neighboring planes comprising of a high density of dopant A 56 will be between 183 μm and 193 nm. The gas removed from vacuum chamber 96 in operation step IV is air. The gas used to backfill vacuum chamber 96 in operation step VIII is argon. After completing operation step 1× the doping superlattice comprising of planes 57 is maintained at 173° K.

### EXAMPLE 3

In example 3 the bulk semiconductor 20 is a 1 mm thick silicon wafer, the dopant A 22 is iron, dopant B is boron, the uniformly doped bulk semiconductor 21 is a 1 mm thick, 6 inch diameter silicon wafer doped with 10¹⁵ iron atoms per cm³ and 10¹⁵ boron atoms per cm³. Iron is a electron donor and boron is an electron acceptor. The saw used to cut the silicon wafer from a crystal ingot is a diamond-tipped inner-hole blade saw. The silicon wafer is mechanically lapped and ground on both sides to obtain a flat surface. To give the wafer a mirror like finish it is polished using a slurry of fine SiO₂ particles in basic NaOH solution. Laser A 76a and Laser B 76b are constant wave diode tunable lasers from New Focus, 2584 Junction Ave, San Jose, Calif., 95134. The part number for the diode tunable lasers is TLB-6324. Laser A 76A is tuned to 1.320 μm and laser B 76B is tuned to 1.316 μm. Optical isolator A 80a and optical isolator B 80b use Faraday Rotators with Yttrium Iron Garnet crystals as the Faraday media. The uniformly doped bulk semiconductor's 21 temperature is maintained between 370° C. and 390° C. while it undergoes steps V-VI as described in the operations section of this invention. The time between operations steps V-VI is 72 hours. If laser A 76A and laser B 76B are both on and operating at 25° C. at a power level between 8.0 mW and 8.5 mW during steps V-VI then the distance between two neighboring planes comprising of a high density of dopant A 56 will be between 120 μm and 130 μm. If laser A 76A is on and operating at 25° C. at a power level between 8.0 mW and 8.5 mW while laser B 76B is off and not operating during steps V-VI then the distance between two neighboring planes comprising of a high density of dopant A 56 will be between 183 nm and 193 nm. The gas removed from vacuum chamber 96 in operation step IV is air. The gas used to backfill vacuum chamber 96 in operation step VIII is argon. After completing operation step IX the doping superlattice comprising of planes 57 is maintained at 173° K. The recombination enhanced motion of iron in silicon was first reported by Kimerling et al, and disclosed in Physica 116B, page 297, 1983.

### EXAMPLE 4

In example 4 the bulk semiconductor 20 is a 1 mm thick silicon wafer, the dopant A 22 is iron, dopant B is boron, the uniformly doped bulk semiconductor 21 is a 1 mm thick, 6 inch diameter silicon wafer doped with 10¹⁵ iron atoms per cm³ and 10¹⁵ boron atoms per cm³. Iron is an electron donor and boron is an electron acceptor. The saw used to cut the silicon wafer from a crystal ingot is a diamond-tipped inner-hole blade saw. The silicon wafer is mechanically lapped and ground on both sides to obtain a flat surface. To give the wafer a mirror like finish it is polished using a slurry of fine SiO₂ particles in basic NaOH solution. Laser A 76a and Laser B 76b are constant wave GaInNAs vertical external-cavity surface emitting lasers as described by Hopkins et al, and disclosed in Electronics Letters, volume 40, number 1, page 30, January 2004. Laser A 76A has an output wavelength at 1.320 μm and laser B 76B has an output wavelength at 1.316 μm. Optical isolator A 80a and optical isolator B 80b use Faraday Rotators with Yttrium Iron Garnet crystals as the Faraday media. The uniformly doped bulk semiconductor's 21 temperature is maintained between 370° C. and 390° C. while it undergoes steps V-VI as described in the operations section of this invention. The time between operations steps V-VI is 72 hours. If laser A 76A and laser B 76B are both on and operating at 5° C. at a power level between 600 mW and 590 mW during steps V-VI then the distance between two neighboring planes comprising of a high density of dopant A 56 will be between 120 μm and 130 μm. If laser A 76A is on and operating at 5° C. at a power level between 600 mW and 590 mW while laser B 76B is off and not operating during steps V-VI then the distance between two neighboring planes comprising of a high density of dopant A 56 will be between 183 nm and 193 nm. The gas removed from vacuum chamber 96 in operation step IV is air. The gas used to backfill vacuum chamber 96 in operation step VIII is argon. After completing operation step IX the doping superlattice comprising of planes 57 is maintained at 173° K.

### CONCLUSIONS, RAMIFICATIONS, AND SCOPE

Accordingly, the reader will see that the method for forming doping superlattices using standing electromagnetic waves of this invention can be used to form a variety of electronic potential structures. Forming each layer of a doping superlattice simultaneously is more time efficient than forming it one layer at a time. In addition, using the method of this invention results in doping superlattices that are identical and equally spaced from one another. Furthermore, the doping superlattices formed by the method of this invention can be altered or recycled to form new electronic potential structures.

While the above description contains many specificities, these should not be construed as limitations on the scope of the invention, but rather as an exemplification of one preferred embodiment thereof. Many other variations are possible. For example:
The uniformly doped bulk semiconductor can be another type of semiconductor doped with other types of dopants with different dopant densities. However, changing the semiconductor and dopants changes the required laser wavelength because the photon energy should be slightly below the semiconductor bandgap. There are numerous semiconductors, insulators, and dopants that can be used.
The uniformly doped bulk semiconductor does not have to be a monocrystal. The uniformly doped bulk semiconductor can be amorphous or polycrystalline however the best uniformity and spacing of the doping superlattice is achieved if the uniformly doped bulk semiconductor is monocrystal.
The thickness of bulk semiconductor is not restricted to 1 mm. The lower the uniformly doped bulk semiconductor absorption coefficient, the greater the sample thickness can be without significantly reducing the quality of the standing optical beam comprising of optical beats.
The temperature of 170° K. in which the doping superlattice comprising of planes, the doping superlattice comprising of a two dimensional array of wires, doping superlattice comprising of a three dimensional array of dots, is maintained at is dependent of the expected lifetime of the application device. In general the lower the temperature of a micro to nano sized electronic potential structure, the longer it will last or maintain its physical properties.
The shape of the reflectors, the shape of the optical beam wave front, and the shape of the surfaces of the uniformly doped bulk semiconductor are not limited to planar if a non-planer doping superlattice is desired. Whatever the component shapes, the resultant pattern of the standing optical beam comprising of optical beats dictates the shape and form of the regions of high dopant A densities and regions of low dopant A densities in the doping superlattice.
Besides crossing two optical beam comprising of optical beats to form a standing optical beam comprising of optical beats, two other ways of doing this are: reflecting a single optical beam comprising of optical beats from a single external reflector so that the reflected optical beam comprising of optical beats overlaps the incoming optical beam comprising of optical beats, and encasing the source of the optical beam comprising of optical beats in an optical resonator or cavity.
If λ_{A}=λ_{B} then only one laser is needed.
More than two lasers, and/or beamsplitters, and/or reflectors, and/or other optical components may be used to create a plurality of standing optical beams comprising of optical beats of various wave front shapes and sizes.
The quality of the optical beams can be improved by using one or more variable actuators, spatial light filters, convex or fresnel lenses, and irises.
The lasers can be pulsed if the pulse width is much greater than the thickness of the bulk semiconductor.
The vacuum pump is not needed if the vacuum chamber is cooled to a low enough temperate such that the gas inside the vacuum chamber condenses to a liquid or solid.
A gas can be used to backfill the vacuum chamber as long as the gas does not chemical react with the uniformly doped bulk semiconductor surface resulting in a significant change in the effective absorption coefficient of the uniformly doped bulk semiconductor.
A gas can be used to backfill the vacuum chamber as long as the gas convection currents do no not significantly disrupt the quality of the standing optical beam comprising of optical beats or significantly reduce the intensity of the standing optical beam comprising of optical beats.
The lasers do not have to be semiconductor lasers. Any coherent light source that can provide the required photon wavelength and power can be used.
The uniformly doped bulk semiconductor diameter does not have to be 6 inches. However, diameters that are too small can cause unwanted diffraction effects and/or minimize the optical power absorbed by the uniformly doped bulk semiconductor.
The time in which the standing optical beam comprising of optical beats exists within the uniformly doped bulk semiconductor is dependent on the desired quality of the doping superlattice. In general, the longer this time, the greater the quality of the doping superlattice.
The uniformly doped bulk semiconductor can be doped with several dopants so that a plurality of sets of planes comprising of a high density of dopant A and sets of planes comprising of a low density of dopant A can be formed. Each dopant would have its own solubility limit in the bulk semiconductor so each set of planes comprising of a high density of dopant A could be formed at particular temperatures. The least soluble dopant would first be formed at the highest temperature and the highest soluble dopant would be formed at the lowest temperature.
The geometry of the regions comprising of a high density of dopant A is not limited to planes, wires, and dots. Other geometry's are possible using various optical components. A few potential geometry's are circles, spheres, cylinders, crisscross, zigzag, and checkered given the correct pattern of standing optical beam comprising of optical beats.

Accordingly, the scope of the invention should be determined not by the embodiments illustrated, but by the appended claims and their legal equivalents.

1. A method for forming a doping superlattice, comprising the steps of:
a. heating a solid to a predetermined temperature,
b. establishing a standing optical beam in said solid at said temperature for a predetermined period of time,
c. cooling said solid to a predetermined temperature.

2. The method of claim 1 wherein said doping superlattice is composed of a n-i-p-i layered structure.

3. The method of claim 1 wherein said doping superlattice is composed of a p-n-p-n layered structure.

4. The method of claim 1 wherein said doping superlattice is composed of a periodic electronic potential structure.

5. The method of claim 1 wherein said doping superlattice is composed of a plurality of planes.

6. The method of claim 1 wherein said doping superlattice is composed of a two dimensional array of wires.

7. The method of claim 1 wherein said doping superlattice is composed of a three dimensional array of dots.

8. The method of claim 1 wherein said solid is a semiconductor.

9. The method of claim 1 wherein said solid is an insulator.

10. The method of claim 1 wherein said standing optical beam is composed of a series of optical beats.

11. A method for converting a solid to a doping superlattice, comprising the steps of:
a. heating said solid to a predetermined temperature,
b. establishing a standing optical beam in said solid at said temperature for a predetermined period of time,
c. cooling said solid to a predetermined temperature.

12. The method of claim 11 wherein said doping superlattice is composed of a n-i-p-i layered structure.

13. The method of claim 11 wherein said doping superlattice is composed of a p-n-p-n layered structure.

14. The method of claim 11 wherein said doping superlattice is composed of a periodic electronic potential structure.

15. The method of claim 11 wherein said doping superlattice is composed of a plurality of planes.

16. The method of claim 11 wherein said doping superlattice is composed of a two dimensional array of wires.

17. The method of claim 11 wherein said doping superlattice is composed of a three dimensional array of dots.

18. The method of claim 11 wherein said solid is a semiconductor.

19. The method of claim 11 wherein said solid is an insulator.

20. The method of claim 11 wherein said standing optical beam is composed of a series of optical beats.
